(19) United States
(12) Patent Application Publication
(10) Pub. No.: US 2008/0224321 A1
(43) Pub. Date: Sep. 18, 2008

(54) CELL DATA FOR SPARE CELL, METHOD OF DESIGNING A SEMICONDUCTOR INTEGRATED CIRCUIT, AND SEMICONDUCTOR INTEGRATED CIRCUIT

(75) Inventor: Junji JINNO, Kanagawa (JP)

Correspondence Address: Young & Thompson, Suite 500, 209 Madison Street, Alexandria, VA, 22314, US

(73) Assignee: NEC ELECTRONICS CORPORATION, Kawasaki (JP)

(21) Appl. No.: 12/046,483

(22) Filed: Mar. 12, 2008

(30) Foreign Application Priority Data
Mar. 12, 2007 (JP) 2007-61360

(51) Int. Cl. H01L 23/48; G06F 17/50

(52) U.S. Cl. 257/773; 716/19; 257/E23.01

(57) ABSTRACT

In a cell base design, when a circuit using a spare cell is corrected, a wiring length is shortened as much as possible, and the number of wiring layers which are affected by correction is reduced. Mask pattern data that expresses the configurations of a signal input terminal and a signal output terminal of a spare cell is set to mask pattern data of a wiring layer that is equal to or higher than a second wiring layer. As a result, the length of a wiring that is connected to the spare cell can be shortened as much as possible.

### BACKGROUND OF THE INVENTION

1. Field of the Invention

The present invention relates to a semiconductor integrated circuit, and more particularly to cell data for a space cell which suppresses a mask correction at the time of correcting a circuit to the minimum, a method of designing a semiconductor integrated circuit by using the cell data, and a semiconductor integrated circuit that is designed by the designing method.

2. Description of the Related Art

As one of the methods of designing the semiconductor integrated circuits, there is a standard cell system. In the standard cell system, it is necessary to manufacture a mask of all layers in each of chips that are different in circuit. Then, when a circuit that has been designed once is corrected, it is necessary to remanufacture the mask in order to change the layout of the cells and wirings. In particular, a mask of a first wiring layer is higher than in masks of other wiring layers in the manufacture costs and in a period of time required for the manufacture. For that reason, it should be avoided to remanufacture the mask of the first wiring layer as much as possible.

A technique by which the remanufacturing of the mask is minimized is disclosed in JP2006-237123.

The technique disclosed in JP 2006-237123 is shown in FIG. 1. In the related art, an input pin of a spare cell 101 is connected to a power supply or a ground wiring by a wiring 201, and an output pin of the spare cell 101 is connected to a wiring 203 that is led to a lowermost wiring layer via an uppermost wiring layer (FIG. 1).

Then, when it is necessary to correct the circuit by the aid of the spare cell 101, the spare cell 101 is reconnected to function cells 103 and 104 by the aid of wirings 201 and 203 (FIG. 2).

### SUMMARY

The present inventors have found the following problems with the above related art.

In the technique disclosed in JP 2006-237123, there is no disclosure that the circuit is designed by the aid of a standard cell system, and it is unclear whether the spare cell is provided as cell data, or not. Even when the spare cell is prepared as the cell data, which portion is prepared as the cell data is not disclosed at all. Accordingly, when the circuit is corrected by the aid of the spare cell, the wiring pattern of the first wiring layer is changed in order to correct the circuit in the shortest pattern with the results that there occurs such a problem that the mask pattern of the first wiring layer is changed, and the costs of the semiconductor integrated circuit is increased. Further, in the technique disclosed in JP2006-237123, the wiring 203 that is connected to the output pin is long, and when the circuit is corrected by connecting the spare cell 101 to the function cells 103 and 104, a signal path becomes long to cause a signal delay. Also, even when the spare cell 101 is not used for correcting the circuit, an excess space is required because the wiring 203 penetrates through the multiple wiring layers (1 to n) twice. As a result, a space for other wirings is compressed.

One embodiment has been made in view of the above circumstances, and therefore an object of the one embodiment is to provide cell data for a spare cell having mask pattern data representative of the configurations of a signal input terminal and a signal output terminal as the mask pattern data of the wiring layers equal to or higher than the second wiring layer.

Even when a cell base is designed by the aid of the cell data for the spare cell to redesign the wiring in order to correct the circuit by the aid of the spare cell, it is necessary to change only the mask patterns of the wiring layers equal to or higher than the second wiring layer, and the mask pattern of the first wiring pattern within the spare cell is not changed. For that reason, it is unnecessary to reproduce the mask for the first wiring layer.

Also, the cell data for the spare cell according to the one embodiment includes the mask pattern data that expresses the configurations of the signal input terminal and the signal output terminal as the mask pattern data of the wiring layers equal to or higher than the second wiring layer. Also, the mask pattern data of the wiring layer higher than the wiring layer having the mask pattern that expresses the configurations of the signal input terminal and the signal output terminal includes no mask pattern data that expresses the configurations of the wirings used for input and output of the signal.

In the cell base design using the cell data for the spare cell according to the present invention, there is no necessity that the wiring of the output pin is led up to the uppermost wiring layer.

According to an aspect of the present invention, the length of the wiring that is connected to the spare cell can be shortened as much as possible while the remanufacture of the mask is suppressed to the minimum.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram for explaining the related art;

FIG. 2 is a diagram for explaining the related art;

FIG. 3 is a diagram for explaining cell data for a spare cell according to an embodiment of the present invention;

FIG. 4A, FIG. 4B, FIG. 4C, FIG. 4D, and FIG. 4E are diagrams for explaining mask pattern data included in the cell data for the spare cell according to the embodiment of the present invention;

FIG. 5 is a diagram for explaining the definition of an n-th wiring layer in the present invention;

FIG. 6 is a flowchart showing a method of designing a semiconductor integrated circuit according to the embodiment of the present invention;

FIG. 7A and FIG. 7B are diagrams for explaining a method of designing the semiconductor integrated circuit according to the embodiment of the present invention;

FIG. 8A and FIG. 8B are diagrams for explaining a method of designing the semiconductor integrated circuit according to the embodiment of the present invention;

FIG. 9A and FIG. 9B are diagrams for explaining a method of designing the semiconductor integrated circuit according to the embodiment of the present invention; and

FIG. 10 is a diagram for explaining a design system of a semiconductor integrated circuit according to the embodiment of the present invention.

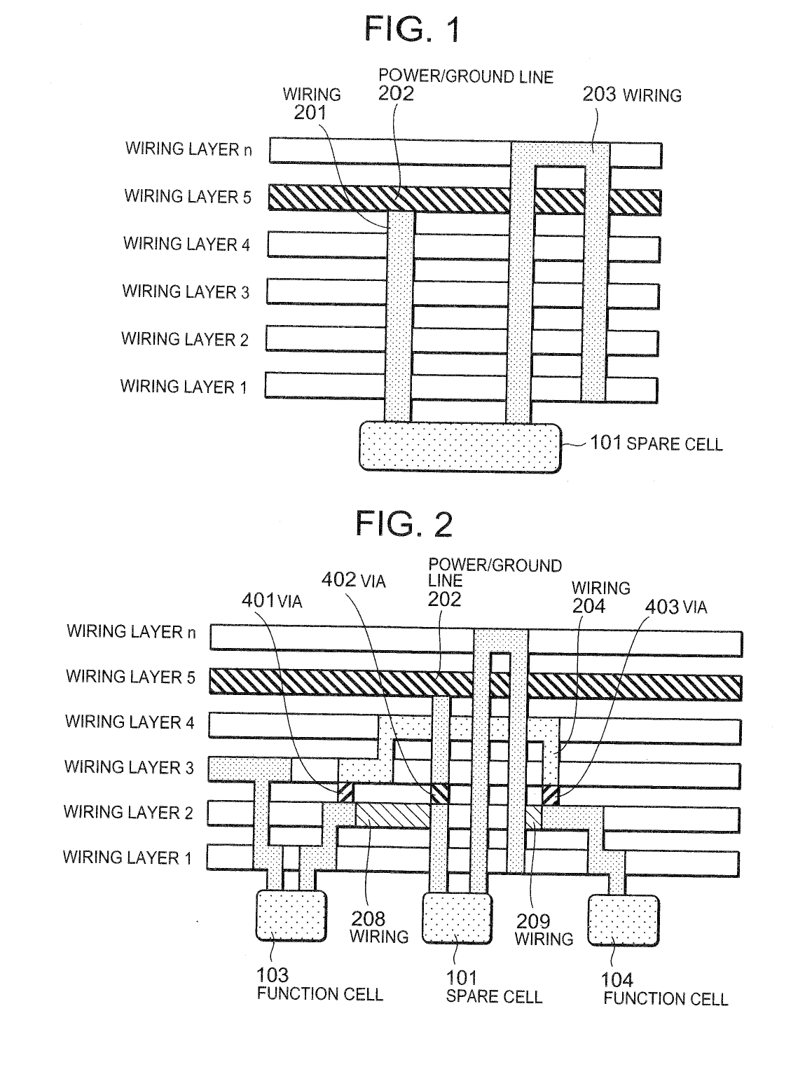

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In the present application, cell data is directed to data for expressing the structure of a cell used in a cell base design, which is the mask pattern data of a photo mask used in the manufacture of a semiconductor integrated circuit. The mask pattern data includes, for example, the data expressive of the configuration of a diffusion layer which is the source/drain of a transistor that is included in the cell, the data expressive of the configuration of a gate electrode, and data expressive of the wirings for supplying a signal or a power supply to the transistor or the configuration of a via.

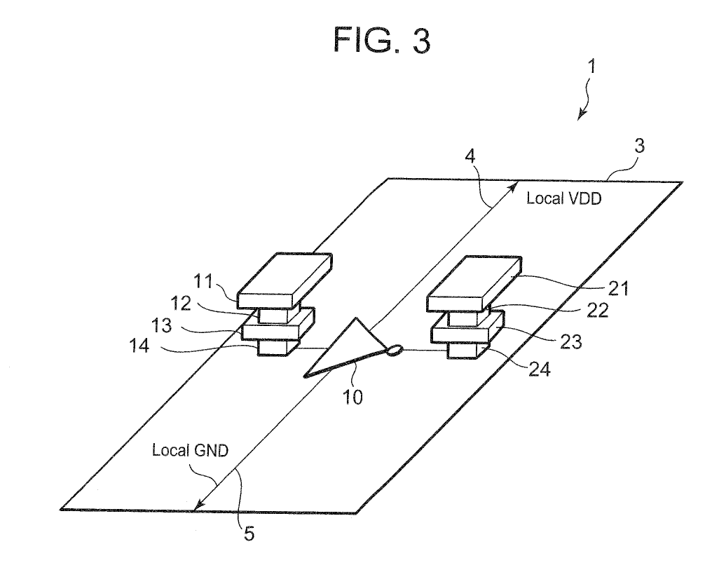

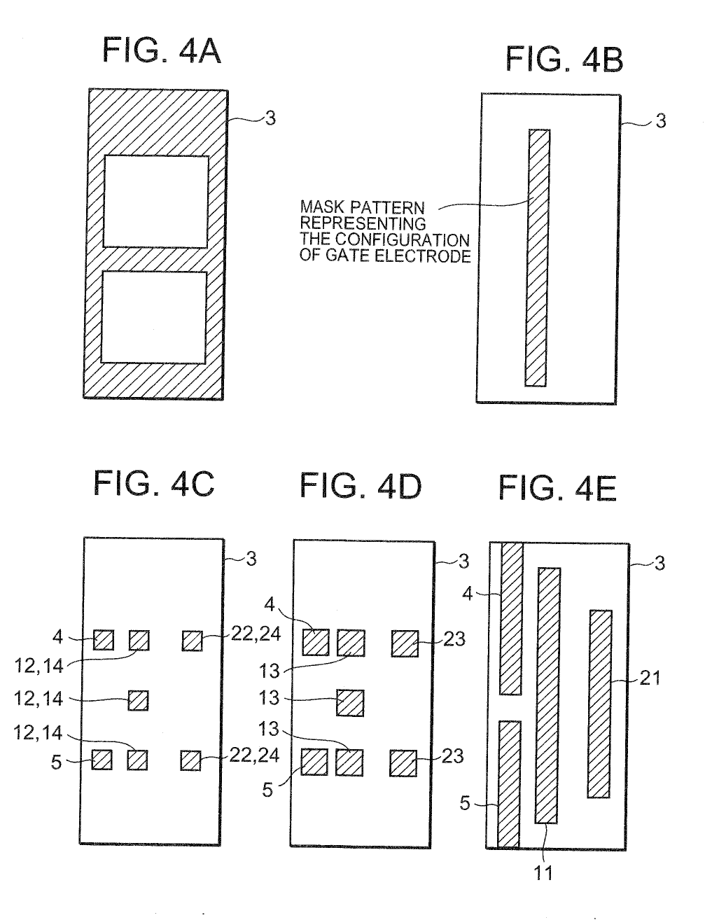

Also, the cell data includes only the mask pattern data of a wiring that extends from a semiconductor substrate to a signal input terminal, and the mask pattern data of a wiring that extends from the semiconductor substrate to a signal output terminal as the mask pattern data that expresses the configuration of a signal wiring for connecting the cells to each other. That is, the cell data does not include the mask pattern data of the signal wiring that connects the signal output terminal of one cell to the signal input terminal of another cell. As will be described later, the mask pattern data of the signal wiring for connecting the cells to each other is designed by an automatic wiring tool. The automatic wiring tool designs the signal wiring that connects between the cells with the origin of the signal input terminal and the signal output terminal. FIGS. 3 and 4 are diagrams for explaining cell data 1 for a spare cell according to this embodiment which is an example of a spare cell having an inverter 10.

The cell data 1 is produced by the aid of a CAD. In FIG. 3, the configuration data that expresses a partial specific structure of the transistor that constitutes an inverter 10 is omitted for simplification. Also, FIG. 3 three-dimensionally expresses the actual configuration for facilitation of understanding, but the cell data 1 is the assembly of the mask pattern data that is two-dimensional configuration data. For example, in FIG. 3, vias 12, 14, 22, and 24 are expressed as a rectangular solid. However, as will be described later, the mask pattern data that expresses the vias 12, 14, 22, and 24 are two-dimensional configuration data that expresses the cross section configuration.

Referring to FIG. 3, reference numeral 11 denotes a signal input terminal that is connected to a gate electrode of a transistor (not shown) that constitutes the inverter 10 through the via 12, a wiring 13 of a first wiring layer, and a via 14. Likewise, referring to FIG. 3, reference numeral 21 denotes a signal output terminal that is connected to a source of a drain of a PMOS transistor and a source of an NMOS transistor (not shown) which constitute the inverter 10.

Also, the inverter 10 is supplied with a power supply from a local power supply wiring 4 and a local ground wiring 5. In FIG. 3, the specific configurations of the wirings 4 and 5 are omitted, but FIG. 4 shows apart of the mask pattern that expresses the configurations of those wirings 4 and 5.

The mask pattern data included in the cell data 1 for the spare cell is exemplified by the configuration of a well where the transistor that constitutes the inverter 10 is formed (FIG. 4A), the configuration of a gate electrode (FIG. 4B), the configurations of the vias 4, 5, 12, 14, 22, and 24 (FIG. 4C), the configurations of wirings 4, 5, 13, and 23 of the first wiring layer (FIG. 4D), and the configurations of the wirings 4, 5, 11, and 21 of the second wiring layer (FIG. 4E). Referring to FIG. 4E, reference numeral 11 denotes the configuration of the signal input terminal, and reference numeral 21 is the configuration of the signal output terminal. Also, referring to FIG. 3, reference numeral 3 denotes a boundary line, and when the mask is a negative mask, a light is shielded in the configuration indicated by oblique lines in FIGS. 4A to 4E.

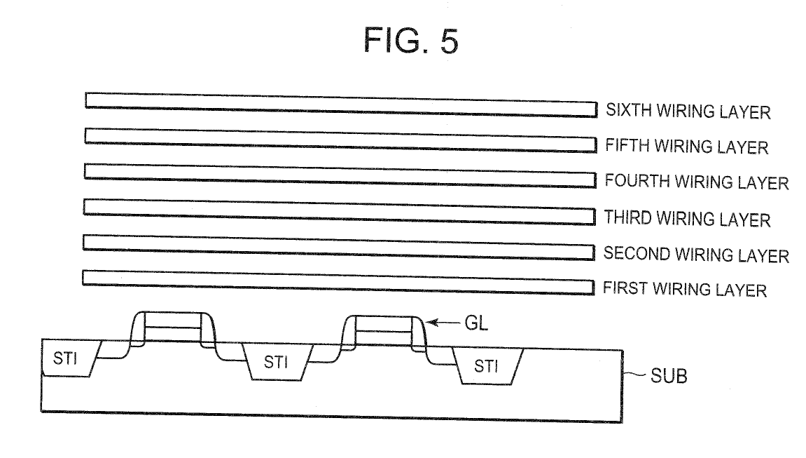

In the present specification, an n-th wiring layer is a wiring layer of n-th when being counted from a metal wiring layer closest to a semiconductor substrate SUB except for a gate electrode layer GL (refer to FIG. 5).

The cell data 1 for the spare cell has no mask pattern data of the wiring for the signal input/output wiring on the wiring layer (in this embodiment, a wiring layer equal to or higher than a third wiring layer) above the wiring layer including the mask pattern data of the signal input terminal 11 and the signal output terminal 21. For that reason, even when the spare cell is used for the semiconductor integrated circuit that has been corrected, there is no case in which the signal wiring is not longer than a required one.

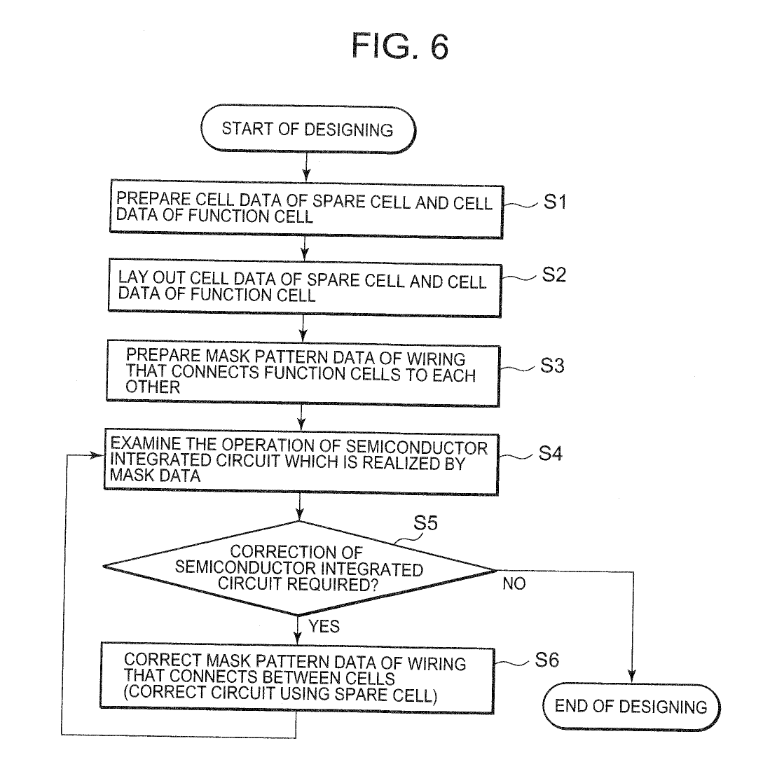

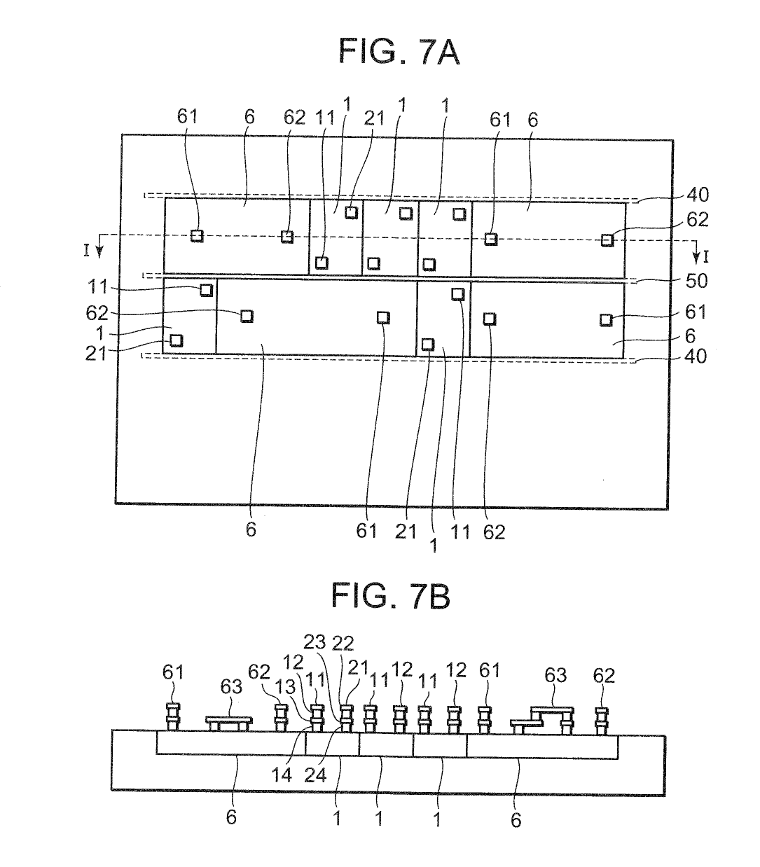

Subsequently, a description will be given of a method of designing a semiconductor integrated circuit using the cell data 1 with reference to a flowchart (FIG. 6) and FIGS. 7A to 9B.

First, in Step S1, the cell data 1 for the spare cell and cell data 6 for a function cell are prepared. The function cell is a cell for realizing a predetermined function. The spare cell is a cell used to correct the circuit, and even when the spare cell is laid out, there is a case in which the spare cell is not connected to another circuit, and is not used for signal processing within a semiconductor integrated circuit device that has been finally actually manufactured.

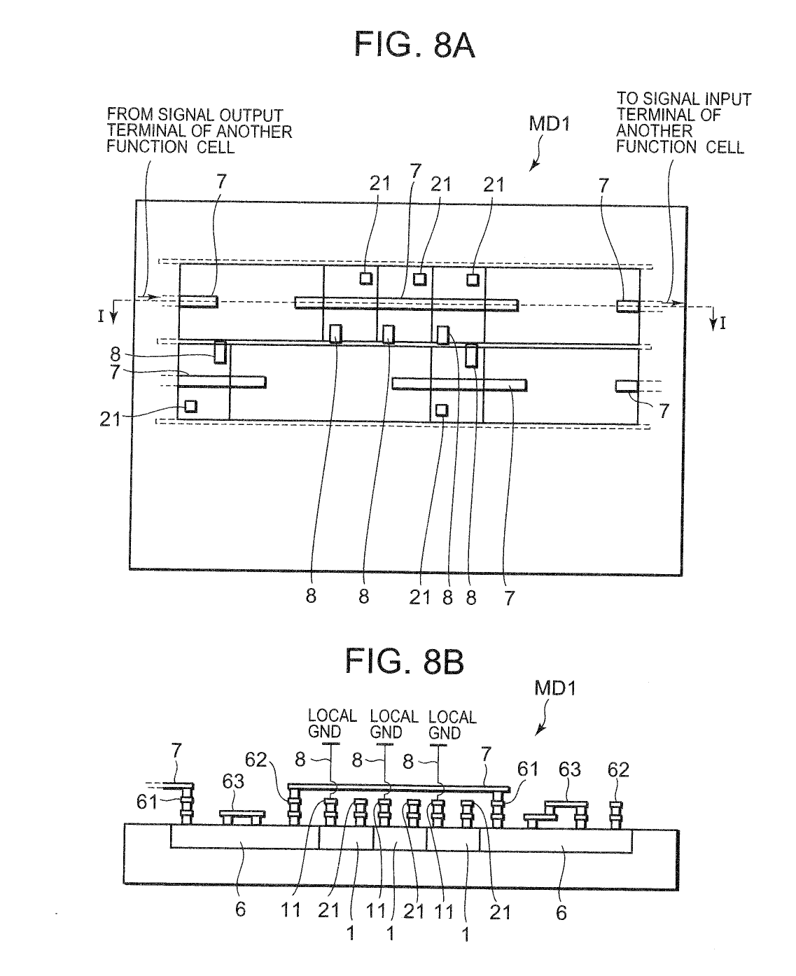

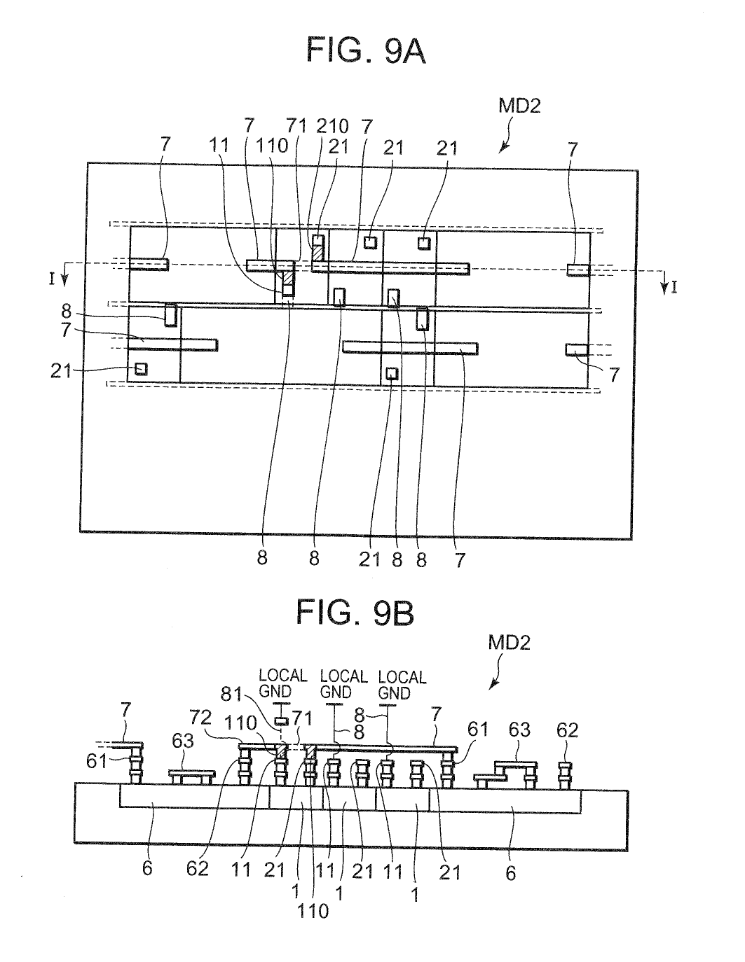

Subsequently, in Step S2, as shown in FIGS. 7A and 7B, the cell data 1 for the spare cell and the cell data 6 for the function cell are laid out to provide layout data 7 that represents the layout of the respective cells on the semiconductor chip. The cell data 1 for the spare cell is laid out in a free space after the layout of the cell data 6 for the function cell has been completed. FIG. 7B is a diagram of FIG. 7A viewed from a direction perpendicular to a section I-I. The same is applied to FIGS. 8A, 8B and 9A, 9B.

Referring to FIG. 7A, reference numeral 40 and 50 denote positions at which the mask patterns of the local power supply wiring 4 and the local ground wiring 5 are laid out, respectively.

As shown in FIG. 7B, the cell data for the function cell includes the mask pattern data of the wiring 63 within the function cell. The mask pattern data of the wiring 63 is included in the cell data as the mask pattern data of the first wiring layer and the second wiring layer. The wiring 63 is omitted in FIG. 7A as well as FIGS. 8A and 9A which will be described later.

In this embodiment, the cell data 6 for the function cell has one signal input terminal 61 and one signal output terminal 62, respectively. However, the number of signal input terminals and the number of signal output terminals are not limited to one, respectively.

At a stage where the processing in Step S2 has been completed, the mask pattern data that expresses the configuration of the wiring that connects the function cells 6 to each other is not produced.

Subsequently, in Step S3, the configuration of the connection wiring that connects the function cells 6 to each other is designed, and the mask pattern data 7 of the connection wiring is produced (FIGS. 8A and 8B). Upon completion of the processing in Step S3, a primary design of mask data MD1 is completed.

In Step S3, it is possible to design the configuration of the wiring 8 that connects the signal input terminal 11 of the spare cell 1 and the local ground wiring 50 at the same time. In FIG. 8B, the wiring 8 is schematically expressed.

On the other hand, at a time point of completing the processing in Step S3, there exist no data of the wiring that is connected to the signal output terminal 21 of the spare cell 1.

Subsequently, in Step S4, it is examined whether the semiconductor integrated circuit that is realized the mask data MD1 that has been primarily designed normally operates, or not. The examination can be conducted by manufacturing the mask on the basis of the primarily designed mask data and manufacturing the real semiconductor integrated circuit device. Alternatively, it is possible to examiner whether the primary designed semiconductor integrated circuit normally operates, or not, through a calculation simulation based on the primarily designed mask data.

As a result of the examination in Step S4, it is determined whether the correction of the primarily designed semiconductor integrated circuit is necessary, or not (Step S5).

As a result of the determination in Step S5, when the primarily designed semiconductor integrated circuit needs to be corrected by the aid of the spare cell, and the spare cell 1 is connected between the function cells 6, the mask pattern data of the wiring that connects between the cells is corrected in Step S6. FIG. 9 shows the mask data MD2 after the mask pattern data of the wiring that connects between the cells has been corrected.

The mask pattern data in portions 71 and 81 indicated by broken lines is included in the primarily designed mask data MD1, but deleted in the corrected mask data MD2.

On the other hand, the mask pattern data 110 and 210 in portions indicated by oblique lines is the configuration data of the wiring which is added in order to connect the spare cell 1 between the function cells 6. The wiring 210 is designed so as to be connected to the wiring 7 with the origin of the output terminal 21.

In the correction of the wiring data according to this embodiment, it is possible to connect the spare cell 1 between the function cells 6 by only correcting the configuration data of the wiring equal to or higher than the second wiring layer. For that reason, it is unnecessary to remanufacture the mask of the first wiring layer. Since the mask of the first wiring layer requires the manufacture costs as compared with the mask of the wiring layer equal to or higher than the second wiring layer, it is unnecessary to remanufacture the mask of the first wiring layer, which is a great advantage.

This embodiment can be realized by preparing the cell data having the input/output terminal configuration of the spare cell which is equal to or higher than the second layer wiring layer as the cell data of the spare cell. Accordingly, it is necessary that the input/output terminal configuration of the spare cell is laid out on the second layer wiring layer or higher. The wiring layers of the cell data having the input terminal configuration and the output terminal configuration can be different from each other. Further, even when there exists the cell data of the plural input terminal configurations, in the case of the wiring layer that is equal to or higher than the second layer wiring layer, the cell data of the respective terminal configurations can be laid out on the separate wiring layers. The same is applied to a case in which the cell data of the plural output terminal configurations exists.

Also, the correction of the wiring data can be realized by providing the semiconductor integrated circuit having the input/output terminal of the spare cell on the second layer wiring layer or higher without remanufacturing the mask of the first layer wiring. The input/output terminal of the spare cell can be laid out on the second layer wiring layer or higher, and the wiring layers on which the input terminal and the output terminal are laid out can be different from each other. Further, even when the plural input terminals exist in the spare cell, in the case of the wiring layer that is equal to or higher than the second layer wiring layer, the respective terminals can be laid out on the separate wiring layers. The same is applied to a case in which the plural output terminal configurations exist in the spare cell.

It is preferable that no wiring that is connected to the input/output terminal is laid out on the wiring layer that is higher than the wiring layer on which the input/output terminal is disposed in order to ensure a space for another wiring.

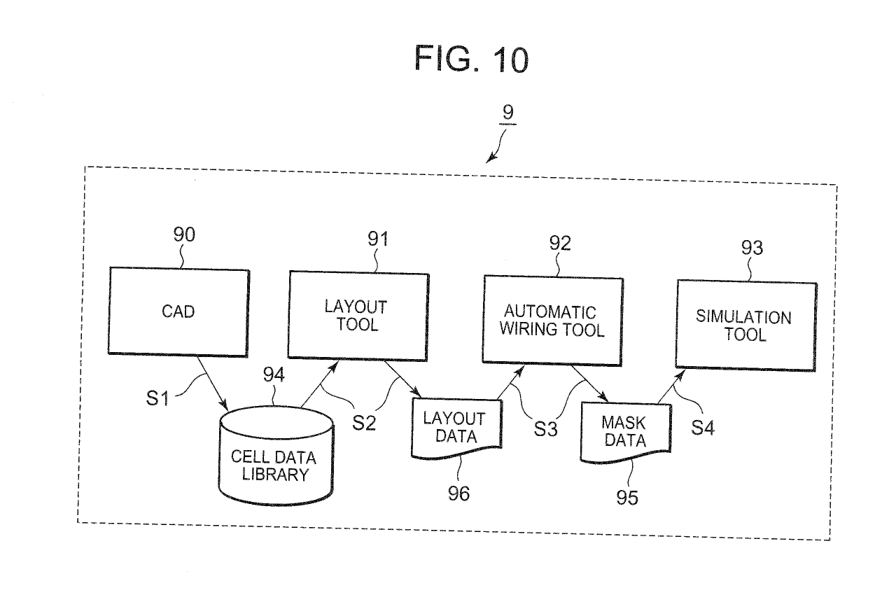

A design system 9 of the semiconductor integrated circuit according to this embodiment is shown in FIG. 10. The design system 9 includes a CAD 90, a layout tool 91, an automatic wiring tool 92, a simulation tool 93, a cell data library 94, mask data 95, and layout data 96.

In Step S1, the processing is conducted by the CAD 90, and the produced cell data is recorded on the cell data library 94. The cell data library 94 is data base that has been recorded on, for example, a hard disk drive.

In Step S2, the processing is conducted by the layout tool 91. The layout tool 91 reads the cell data 1 of the spare cell or the cell data 6 of the function cell from the cell data library 94, and outputs the layout data 96 representative of the layout of those cell data. The layout tool is a computer that installs layout software. The layout data 96 is saved in a hard disk drive of the computer that constitutes the layout tool, and is transferred to another computer on a network or through a data recording medium such as a CD-ROM as the occasion demands.

In Step S3, the processing is conducted by the automatic wiring tool 92. The automatic wiring tool 92 produces the mask pattern data expressive of the configuration of the wiring that connects the function cells 6 to each other on the basis of the layout data 96, and adds the mask pattern data to the layout data 96 to output the mask data MD. The automatic wiring tool 92 is a computer that installs the automatic wiring software. The mask data MD is saved in the hard disk drive of the computer that constitutes the layout tool, and is transferred to another computer on the network or through the data recording medium such as a CD-ROM as the occasion demands.

In the case where the examination of Step S4 is conducted by the computer simulation, the simulation tool 93 is used. The simulation tool 93 is a computer that installs the software which simulates the operation of the semiconductor integrated circuit.

In Step S5, the processing is conducted by using the layout tool 91 and the automatic wiring tool 92. First, in the layout tool 91, the correction information on which spare cell is used in correction of the circuit, and to which position of the circuit the spare cell is inserted is added to the layout data 96. Then, the configuration data of the wiring is corrected by using the automatic wiring tool 92 with reference to the correction information so that the spare cell is connected to the function cell.

The plural tools 90, 91, 92, and 93 that constitute the design system of this embodiment can be formed of the separate computers, or can be formed of the same computer.

It is apparent that the present invention is not limited to the above embodiments, but may be modified and changed without departing from the scope and spirit of the invention.

What is claimed is:

1. A cell data for a spare cell comprising:
a data expressing configurations of an input and an output terminals of a signal, said data included in a mask pattern data indicative of a wiring layer formed on a layer equal to or higher than a second wiring layer.

2. The cell data for a spare cell according to claim 1, further comprising:
another data expressing a configuration of a signal line connected to said input terminal or said output terminal, wherein said another data is not included in another mask pattern data indicative of another wiring layer formed on a higher layer than said second wiring layer.

3. The cell data for a spare cell according to claim 1, wherein said data includes a first data expressing a configuration of said input terminal and a second data expressing a configuration of said output terminal, and said first data is included in a first mask pattern data indicative of one wiring layer and said second data is included in a second mask pattern data indicative of another wiring layer.

4. The cell data for a spare cell according to claim 1, wherein said data is included in a mask pattern data indicative of said second wiring layer.

5. A method of designing a semiconductor integrated circuit, comprising:
producing a cell data for a spare cell having a data expressing configurations of an input and an output terminals of a signal, said data included in a mask pattern data indicative of a wiring layer formed on a layer equal to or higher than a second wiring layer.

6. The method of designing a semiconductor integrated circuit according to claim 5, further comprising:
correcting another data indicative of a signal line connected to said input terminal or said output terminal when a correction of said semiconductor integrated circuit is necessary.

7. A method of designing a semiconductor integrated circuit, comprising:
preparing a cell data for a spare cell having a data expressing configurations of an input and an output terminals of a signal, said data included in a mask pattern data indicative of a wiring layer formed on a layer equal to or higher than a second wiring layer, and a cell data for a function cell performing a predetermined function;
performing a layout of said cell data for said spare cell and said cell data for said function cell;
producing another data expressing a configuration of another wiring connected to said function cell;
examining an operation of said semiconductor integrated circuit and determining whether a correction of said semiconductor integrated circuit is necessary or not; and
correcting said another data to connect one end of said another wiring with one of said signal input and output terminals in said second wiring layer when said correction of said semiconductor integrated circuit is necessary.

8. The method of designing a semiconductor integrated circuit according to claim 7, further comprising:
producing a data expressing a configuration of a wiring connecting said signal input terminal with a power supply wiring.

9. A semiconductor integrated circuit comprising:
a plurality of wiring layers;
a function cell performing a predetermined function; and
a spare cell having an input and an output terminals formed on a layer equal to or higher than a second wiring layer of said plurality of wiring layers.

10. The semiconductor integrated circuit according to claim 9, wherein
said input and output terminals are formed on a same layer.

11. The semiconductor integrated circuit according to claim 9, wherein said input and output terminals are formed on a plurality of wiring layers.

12. The semiconductor integrated circuit according to claim 9, wherein
said input and output terminals are connected to said function cell in a lower layer than said layer.

13. The semiconductor integrated circuit according to claim 9, wherein
said spare cell does not have a wiring layer in a higher layer than said layer.
